(19) United States
(12) Patent Application Publication
(10) Pub. No.: US 2021/0356859 A1
(43) Pub. Date: Nov. 18, 2021

(54) MANUFACTURING METHODS OF MASK AND DISPLAY PANEL

(71) Applicant: HKC CORPORATION LIMITED, SHENZHEN (CN)

(72) Inventor: HUAILIANG HE, SHENZHEN (CN)

(21) Appl. No.: 16/319,487

(22) PCT Filed: Nov. 2, 2018
(86) PCT No.: PCT/CN2018/113560

§ 371 Date: Jan. 22, 2019

(30) Foreign Application Priority Data
Oct. 8, 2018 (CN) 201811167258.5

(51) Int. Cl. G03F 1/84; H01L 27/12

(52) U.S. Cl. CPC G03F 1/84; H01L 27/1288

(57) ABSTRACT

This application discloses manufacturing methods of a mask and a display panel. The manufacturing method of a mask includes: simulating an exposure condition of a component correspondingly produced for the mask; manufacturing the component, and recording experimental data; comparing the experimental data with production data recorded in a production environment to form reference data; and manufacturing the mask of the component according to the reference data.

This application claims priority to Chinese Patent Application No. CN201811167258.5, filed with the Chinese Patent Office on Oct. 8, 2018 and entitled “MANUFACTURING METHODS OF MASK AND DISPLAY PANEL”, which is incorporated herein by reference in its entirety.

### TECHNICAL FIELD

This application relates to the field of display technologies, and more specifically, relates to manufacturing methods of a mask and a display panel.

### BACKGROUND

The description herein provides only background information related to this application, but does not necessarily constitute the existing technology.

A liquid crystal display has been widely applied thanks to many advantages of a thin machine body, power saving, no radiation and the like. Most of liquid crystal displays known to the inventor are backlight type liquid crystal displays including liquid crystal panels and backlight modules. The working principle of the liquid crystal panel is to place liquid crystal molecules into two parallel glass substrates, and apply a drive voltage onto the two glass substrates to control rotating directions of the liquid crystal molecules, so as to refract light rays of the backlight module to generate a picture.

The liquid crystal display technology is improving constantly. In the increasingly developing market, each manufacturer deploys in-plant resources to increase the productivity, so that on one hand, the productivity may be increased, and on the other hand, the in-plant production is more reasonable.

Different exposure machines are needed in a manufacture procedure of an array substrate and a manufacture procedure of a color film substrate, which leads to high manufacturing costs of a mask.

### SUMMARY

In view of the abovementioned shortcomings, to solve the technical problems of this application, this application provides manufacturing methods of a mask and a display panel so as to reduce the mask manufacturing costs.

To achieve the abovementioned objective, this application provides a manufacturing method of a mask. The manufacturing method of a mask comprises:

simulating, in an experimental environment, an exposure condition of a component correspondingly produced for the mask;

manufacturing the component in the experimental environment, and recording experimental data;

comparing the experimental data with production data recorded in a production environment to form reference data; and

manufacturing the mask of the component according to the reference data.

Optionally, the component comprises a supporting column. The exposure condition comprises a baking parameter, an exposure parameter and a developing parameter. The experimental data comprises first line width data of the component. The first line width data corresponds to a first opening width of the mask under the same exposure condition. The production data comprises second line width data of the component and second opening width data of the corresponding mask. The reference data comprises line width ratios of the component to the corresponding mask thereof under the production environment and the experimental environment.

Optionally, the baking parameter comprises a baking temperature and baking time. The developing parameter comprises developing time. The exposure parameter comprises an exposure dose and the first opening width of the mask.

Optionally, a value of the exposure dose ranges from 40 to 50 mj/cm², and a value of the first opening width ranges between 200 and 300 um.

Optionally, a multiplicity of groups of exposure conditions is provided, and the baking parameter and the developing parameter of each group are the same.

Optionally, the step of simulating the exposure condition of the supporting column in the experimental environment comprises: filtering out a first wavelength, which is different from that in an exposure machine in the production environment, in an exposure machine in the experimental environment.

Optionally, the first wavelength ranges between 300 nm and 350 nm.

Optionally, the filtered out first wavelength is 333 nm.

Optionally, the supporting column comprises a main supporting column and a sub supporting column. The exposure condition of manufacturing the main supporting column is the same as that of manufacturing the sub supporting column.

This application further discloses a manufacturing method of a mask. The manufacturing method of a mask comprises:

simulating an exposure condition of a supporting column in an experimental environment;

manufacturing the supporting column in the experimental environment, and recording experimental data;

comparing the experimental data with production data recorded in a production environment to form reference data; and

manufacturing the mask of the supporting column according to the reference data.

The exposure condition comprises a baking parameter, an exposure parameter and a developing parameter. The experimental data comprises first line width data of the supporting column. The first line width data corresponds to a first opening width of the mask under the same exposure condition. The production data comprises second line width data of the supporting column and second opening width data of the corresponding mask. The reference data comprises line width ratios of the supporting column to the corresponding mask thereof under the production environment and the experimental environment. A multiplicity of groups of exposure conditions is provided. The baking parameter and the developing parameter of each group are the same.

The baking parameter comprises a baking temperature and baking time. The developing parameter comprises developing time. The exposure parameter comprises an exposure dose and the first opening width of the mask.

Optionally, a value of the exposure dose ranges from 40 to 50 mj/cm², and a value of the first opening width ranges between 200 and 300 um.

The step of simulating the exposure condition of the supporting column in the experimental environment comprises: filtering out a first wavelength, which is 333 nm, in an exposure machine in the experimental environment.

The supporting column comprises a main supporting column and a sub supporting column. The exposure condition of manufacturing the main supporting column is the same as that of manufacturing the sub supporting column.

This application further discloses a manufacturing method of a display panel. The display panel comprises a mask. The manufacturing method of a display panel comprises:

simulating, in an experimental environment, an exposure condition of a component correspondingly produced for the mask;

manufacturing the component in the experimental environment, and recording experimental data;

comparing the experimental data with production data recorded in a production environment to form reference data; and

manufacturing the mask of the component according to the reference data.

The mask of the supporting column requires to be manufactured under the production environment, so that only the data generated in the production environment is available for reference. A mask meeting production requirements may be only manufactured successfully based on manufacturing a plenty of test masks, so that extremely high costs are needed. In this application, the exposure condition of the supporting column is simulated under the experimental environment, and there are two groups of data available for reference for the same mask under the production environment and the experimental environment, so that the accuracy is substantially improved, and the costs of manufacturing the mask may be effectively reduced.

### BRIEF DESCRIPTION OF DRAWINGS

The accompanying drawings included are used for helping understand the embodiments of this application, constitute a part of this specification, illustrate examples of the embodiments of this application and, together with the description, serve to explain the principles of this application. Apparently, the accompanying drawings in the following description merely show some embodiments of this application, and persons of ordinary skill in the art may still derive other drawings from these accompanying drawings without creative effort. In the figures:

FIG. 1 is a schematic structural diagram of a liquid crystal display panel of one embodiment of this application.

FIG. 2 is a schematic diagram of a manufacturing method of a mask of one embodiment of this application.

FIG. 3 is a schematic diagram of a frequency spectrum contrast of a VNS exposure machine and a Canon exposure machine of one embodiment of this application.

FIG. 4 is a schematic diagram of a filtered wavelength of one embodiment of this application.

FIG. 5 is a schematic diagram of a manufacturing method of a mask of a supporting column of another embodiment of this application.

### DETAILED DESCRIPTION

Specific structures and functional details disclosed herein are merely representative, and are intended to describe the objectives of the exemplary embodiments of this application. However, this application may be specifically implemented in many alternative forms, and should not be construed as being limited to the embodiments set forth herein.

In the description of this application, it should be understood that orientation or position relationships indicated by the terms such as “center”, “transverse”, “on”, “below”, “left”, “right”, “vertical”, “horizontal”, “top”, “bottom”, “inside”, and “outside” are based on orientation or position relationships shown in the accompanying drawings, and are used only for ease and brevity of illustration and description, rather than indicating or implying that the mentioned apparatus or component must have a particular orientation or must be constructed and operated in a particular orientation. Therefore, such terms should not be construed as limiting of this application. In addition, the terms such as “first” and “second” are used only for the purpose of description, and should not be understood as indicating or implying the relative importance or implicitly specifying the number of the indicated technical features. Therefore, a feature defined by “first” or “second” can explicitly or implicitly include one or more of said features. In the description of this application, unless otherwise stated, “a plurality of” means two or more than two. In addition, the terms “include”, “comprise” and any variant thereof are intended to cover non-exclusive inclusion.

In the description of this application, it should be noted that unless otherwise explicitly specified or defined, the terms such as “mount”, “install”, “connect”, and “connection” should be understood in a broad sense. For example, the connection may be a fixed connection, a detachable connection, or an integral connection; or the connection may be a mechanical connection or an electrical connection; or the connection may be a direct connection, an indirect connection through an intermediary, or internal communication between two components. Persons of ordinary skill in the art may understand the specific meanings of the foregoing terms in this application according to specific situations.

The terminology used herein is for the purpose of describing specific embodiments only and is not intended to be limiting of exemplary embodiments. As used herein, the singular forms “a”, “an” and “the” are intended to include the plural forms as well, unless the context clearly indicates otherwise. It should be further understood that the terms “include” and/or “comprise” when used in this specification, specify the presence of stated features, integers, steps, operations, elements, and/or components, but do not preclude the presence or addition of one or more other features, integers, steps, operations, elements, components, and/or combinations thereof.

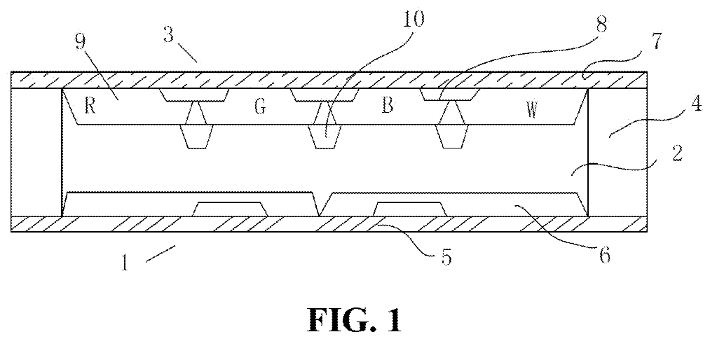

FIG. 1 is a schematic structural diagram of a liquid crystal display panel. The liquid crystal panel includes:

a first substrate 1, a liquid crystal box 2 and a second substrate 3. The first substrate and the second substrate are oppositely arranged in parallel. The liquid crystal box is located between the first substrate and the second substrate. The peripheries of the first substrate and the second substrate are fixed through a plastic frame 4. The first substrate includes a first glass substrate 5, and active switch arrays 6 are arranged on the first substrate. The second substrate includes a second glass substrate 7. Black matrixes 8, a color resist layer 9 and supporting columns 10 are formed on the second glass substrate in sequence. The color resist layer is provided with four color resists corresponding to each pixel, where the four color resists are respectively a red color resist R, a green color resist G, a blue color resist B and a white color resist W. The color resists are arranged between two adjacent black matrixes. The supporting columns are arranged between two adjacent color resists.

This application is further described below with reference to the accompanying drawings and optional embodiments.

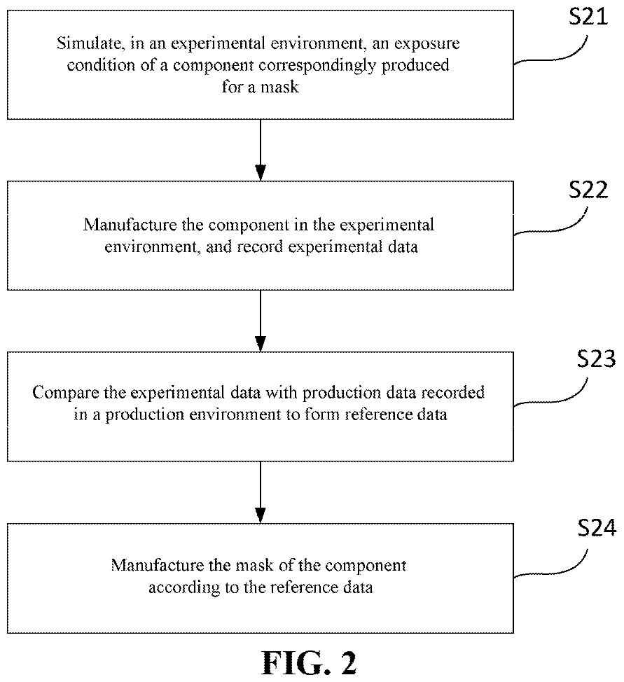

Referring to FIG. 2 to FIG. 4, one embodiment of this application discloses a manufacturing method of a mask. The manufacturing method of a mask includes:

S21, simulating, in an experimental environment, an exposure condition of a component correspondingly produced for the mask;

S22, manufacturing the component in the experimental environment, and recording experimental data;

S23, comparing the experimental data with production data recorded in a production environment to form reference data; and

S24, manufacturing the mask of the component according to the reference data.

The mask requires to be manufactured under the production environment, so that only the data generated in the production environment is available for reference. A mask meeting production requirements may be only manufactured successfully based on manufacturing a plenty of test masks, so that extremely high costs are needed. In this application, the exposure condition of the supporting column is simulated under the experimental environment, and there are two groups of data available for reference for the same mask under the production environment and the experimental environment, so that the accuracy is substantially improved, and the costs of manufacturing the mask may be effectively reduced.

The component of this application also may be a component that needs a mask manufacture procedure in the display panel, such as a black matrix, a color resist, a data line, a scanning line, or a supporting column. The supporting column is used as an example for description below.

In one embodiment, the component includes a supporting column. The exposure condition includes a baking parameter, an exposure parameter and a developing parameter. The experimental data includes first line width data of the component. The first line width data corresponds to a first opening width of the mask under the same exposure condition. The production data includes second line width data of the component and second opening width data of the corresponding mask. The reference data includes line width ratios of the component to the corresponding mask thereof under the production environment and the experimental environment.

The supporting column is relatively high in the display panel, and a subtle difference of the size of the mask may be amplified in the manufacture procedure, so that a requirement on a mask corresponding to the supporting column is relatively high, and a qualified mask may be only manufactured through repeated tests. Therefore, the manufacturing costs are higher than those of other masks, and the cost reduction effect is obvious.

Referring to Table 1, in one embodiment, the baking parameter includes a baking temperature and baking time. The developing parameter includes developing time. The exposure parameter includes an exposure dose and the first opening width of the mask. A value of the exposure dose ranges from 40 to 50 mj/cm², and a value of the first opening width ranges between 200 and 300 um.

TABLE 1
Use a simulated Canon exposure machine
to set different exposure conditions
Use a simulated Canon exposure machine
to set different exposure conditions

| | | |
|---|---|---|
| | | Developer |
| Hot-plate | Expouse | (KOH 0.042%) |

| ITEM | Temp | Time | Dose | Gap | Time |
|---|---|---|---|---|---|
| 1 | 90 | 100 | 50 | 200 | 70 |
| 2 | 90 | 100 | 50 | 300 | 70 |
| 3 | 90 | 100 | 60 | 250 | 70 |
| 4 | 90 | 100 | 40 | 250 | 70 |

TABLE 2
Characteristic values of the main PS of the simulated
exposure machine under different exposure conditions

| | | | | Main supporting column (PS) | | | | | |
|---|---|---|---|---|---|---|---|---|---|
| | | | | | | | | Difference | Difference |
| | | | | | | | | between | between |
| | After Oven | | | | | | | upper and | upper and |
| | Height of | Height of | | Upper | Upper | Lower | Lower | lower | lower |
| | main PS | sub PS | | bottom | bottom | bottom | bottom | bottoms | bottoms |
| ITEM | (Main PSH) | (Sub PSH) | Step | X | Y | X | Y | ΔX | ΔY |
| 1 | 3.15 | 2.8 | 0.35 | 22.3 | 22.52 | 38.75 | 34.55 | 16.45 | 12.03 |
| 2 | 3.12 | 2.82 | 0.3 | 24.11 | 24.11 | 40.28 | 43.67 | 16.17 | 19.56 |
| 3 | 3.17 | 2.81 | 0.36 | 24.88 | 25.3 | 38.76 | 40.26 | 13.88 | 14.96 |
| 4 | 3.12 | 2.78 | 0.34 | 21.89 | 22.06 | 35.26 | 40.39 | 13.37 | 18.33 |

TABLE 3
Characteristic values of the sub PS of the simulated
exposure machine under different exposure conditions

| | | | | Sub PS | | | | | |
|---|---|---|---|---|---|---|---|---|---|
| | | | | | | | | Difference | Difference |
| | | | | | | | | between | between |
| | | | | | | | | upper and | upper and |
| | After Oven | | | Upper | Upper | Lower | Lower | lower | lower |
| | Main | Sub | | bottom | bottom | bottom | bottom | bottoms | bottoms |
| ITEM | PSH | PSH | Step | X | Y | X | Y | ΔX | ΔY |
| 1 | 3.15 | 2.8 | 0.35 | 29.32 | 22.46 | 50.52 | 59.63 | 21.2 | 37.17 |
| 2 | 3.12 | 2.82 | 0.3 | 30.35 | 35.61 | 64.23 | 66.98 | 33.88 | 31.37 |
| 3 | 3.17 | 2.81 | 0.36 | 32.56 | 38.75 | 59.85 | 68.72 | 27.29 | 29.97 |
| 4 | 3.12 | 2.78 | 0.34 | 28.44 | 33.42 | 55.14 | 62.18 | 26.7 | 28.76 |

Referring to Tables 2 and 3, it can be seen from the experimental data that values in these ranges cause relatively small supporting column step differences and are all close to the actual size of the supporting column.

In one embodiment, a multiplicity of groups of exposure conditions is provided, and the baking parameter and the developing parameter of each group are the same.

A research shows that exposure-related parameters have relatively large impact on the size of the supporting column. To highlight main factors affecting the size of the supporting column, the relatively stable baking parameter and developing parameter may be fixed, but the exposure parameter having the relatively high impact is emphatically changed, so that the data analysis difficulty may be effectively reduced, and little impact is caused on the accuracy of the data.

In one embodiment, the step of simulating the exposure condition of the supporting column in the experimental environment includes: filtering out a first wavelength, which is different from that in an exposure machine in the production environment, in an exposure machine in the experimental environment.

To enable the data of the experimental environment and the production environment to be comparable, light sources generated by exposure machines under the two environments are needed, and particularly wavelengths require to be kept consistent as much as possible, but it is very hard to achieve complete consistency, and extremely high costs may be caused. Therefore, a compromising way is to select greatly different wavelengths and filter out a different first wavelength through a filter plate, so that a light source close to that of the production environment may be obtained under the condition of relatively low costs.

In one embodiment, the first wavelength ranges between 300 nm and 350 nm. Further optionally, the filtered out first wavelength is 333 nm.

Generally, a Canon exposure machine is adopted in the manufacture procedure of an array substrate, and a VNS exposure machine is used in the manufacture procedure of a color film substrate. Therefore, to use the Canon exposure machine in the manufacture procedure of the color film substrate, frequency spectrums of the two exposure machines require to be compared.

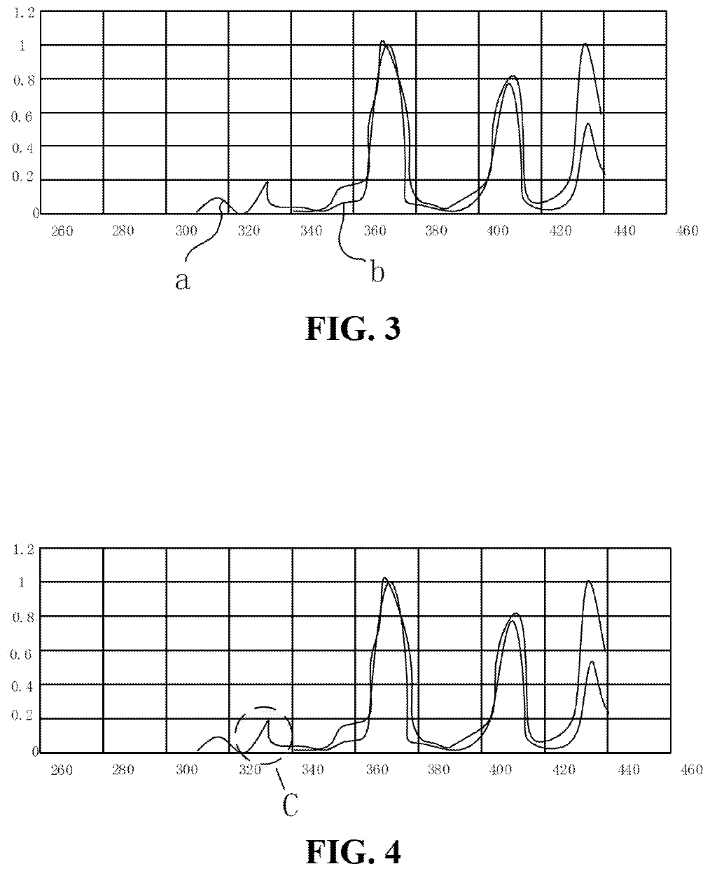

Referring to FIG. 3, a represents the frequency spectrum of the VNS exposure machine, and b represents the frequency spectrum of the Canon exposure machine. Through experimental data comparison, it is found that the exposure machine in a laboratory has an obvious peak wave band between 300 nm and 350 nm and is greatly different from the exposure machine in the production environment, so that filtering the wavelength within this range may obviously reduce the light source difference between the two exposure machines.

It can be seen from the experimental data that 333 nm is a wavelength where the two exposure machines have a larger difference, and is a peak value of a wavelength band shown in a region C in FIG. 4, so that this wavelength is filtered out emphatically.

In one embodiment, the supporting column includes a main supporting column and a sub supporting column. The exposure condition of manufacturing the main supporting column is the same as that of manufacturing the sub supporting column.

The same exposure condition is favorable for parallelly comparing the data of the main supporting column and the sub supporting column to find out mask opening data required by supporting columns of different sizes. Actually, the main supporting column and the sub supporting column represent the supporting columns of different sizes. As the supporting column manufactured in the experimental environment does not need to be applied to production, from the perspective of saving time and improving efficiency, it is very appropriate to collect a multiplicity of groups of data simultaneously since the supporting columns of various sizes are manufactured on a glass plate through one mask manufacture procedure, and the manufacturing shall not be restricted by production conditions.

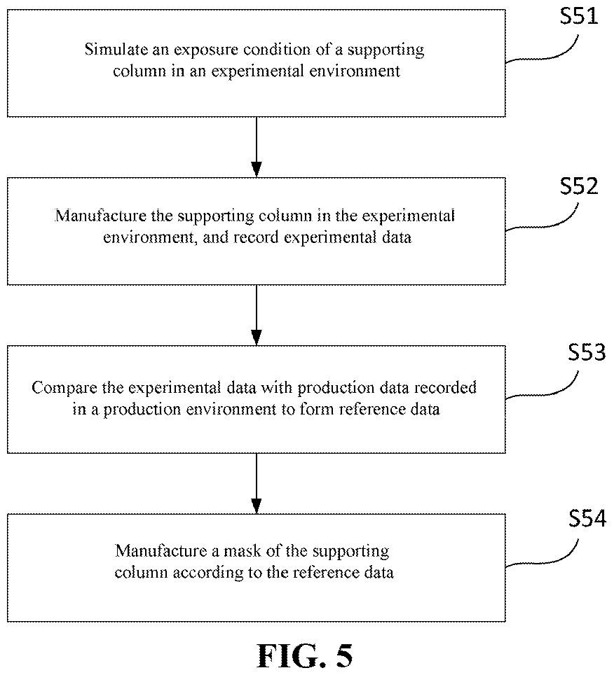

As shown in FIG. 5, the embodiment of this application further discloses a mask

manufacturing method of a supporting column. The manufacturing method includes:

S51, simulating an exposure condition of a supporting column in an experimental environment;

S52, manufacturing the supporting column in the experimental environment, and recording experimental data;

S53, comparing the experimental data with production data recorded in a production environment to form reference data; and

S54, manufacturing the mask of the supporting column according to the reference data.

The exposure condition includes a baking parameter, an exposure parameter and a developing parameter. The experimental data includes first line width data of the supporting column. The first line width data corresponds to a first opening width under the same exposure condition. The production data includes second line width data of the supporting column and second opening width data of the corresponding mask. The reference data includes line width ratios of the supporting column to the corresponding mask thereof under the production environment and the experimental environment. A multiplicity of groups of exposure conditions is provided. The baking parameter and the developing parameter of each group are the same.

The baking parameter includes a baking temperature and baking time. The developing parameter includes developing time. The exposure parameter includes an exposure dose and the first opening width of the mask.

A value of exposure dose ranges from 40 to 50 mj/cm², and a value of the first opening width ranges between 200 and 300 um.

The step of simulating the exposure condition of the supporting column in the experimental environment includes: filtering out a first wavelength, which is 333 nm, in an exposure machine in the experimental environment.

The supporting column includes a main supporting column and a sub supporting column. The exposure condition of manufacturing the main supporting column is the same as that of manufacturing the sub supporting column.

An implementation effect of this application is directly related to an acquired data volume. Therefore, to constantly enhance the effect, a database may be built, and the reference data is written into the database for storage.

The mask requires to be manufactured under the production environment, so that only the data generated in the production environment is available for reference. A mask meeting production requirements may be only manufactured successfully based on manufacturing a plenty of test masks, so that extremely high costs are needed. In this application, the exposure condition of the supporting column is simulated under the experimental environment, and there are two groups of data available for reference for the same mask under the production environment and the experimental environment, so that the accuracy is substantially improved, and the costs of manufacturing the mask may be effectively reduced.

The supporting column is relatively high in the display panel, and a subtle difference of the size of the mask may be amplified in the manufacture procedure, so that the supporting column has a relatively high requirement on the corresponding mask, and a qualified mask may be only manufactured through repeated tests. Therefore, the manufacturing costs are higher than those of other masks, and the cost reduction effect is obvious.

Exposure-related parameters have relatively large impact on the size of the supporting column. To highlight main factors affecting the size of the supporting column, the relatively stable baking parameter and developing parameter may be fixed, but the exposure parameter having the relatively large impact is emphatically changed, so that the data analysis difficulty may be effectively reduced, and little impact is caused on the accuracy of the data.

Referring to Tables 2 and 3, it can be seen from the experimental data that values in the ranges provided by Table 1 cause relatively small supporting column step differences and are all close to the actual size of the supporting column.

To enable the data of the experimental environment and the production environment to be comparable, light sources generated by exposure machines under the two environments are needed, and particularly wavelengths require to be kept consistent as much as possible, but it is very hard to achieve complete consistency, and extremely high costs may be caused. Therefore, a compromising way is to select greatly different wavelengths and filter out a different first wavelength through a filter plate, so that a light source close to that of the production environment may be obtained under the condition of relatively low costs.

Generally, a Canon exposure machine is adopted in the manufacture procedure of the array substrate, and a VNS exposure machine is used in the manufacture procedure of the color film substrate. Therefore, to use the Canon exposure machine in the manufacture procedure of the color film substrate, frequency spectrums of the two exposure machines require to be compared.

Referring to FIG. 3, a represents the frequency spectrum of the VNS exposure machine, and b represents the frequency spectrum of the Canon exposure machine. Through experimental data comparison, it is found that the exposure machine in the laboratory is greatly different from the exposure machine in the production environment because of an obvious peak wave band between 300 nm and 350 nm, so that filtering the wavelength within this range may obviously reduce the light source difference between the two exposure machines.

It can be seen from the experimental data that 333 nm is a wavelength where the two exposure machines are greatly different, and is a peak value of a wavelength band as shown in a region C in FIG. 4, so that this wavelength is filtered out emphatically.

The same exposure condition is favorable for parallelly comparing the data of the main supporting column and the sub supporting column to find out mask opening data required by supporting columns of different sizes. Actually, the main supporting column and the sub supporting column represent the supporting columns of different sizes. As the supporting column manufactured in the experimental environment does not need to be applied to production, from the perspective of saving time and improving efficiency, it is very appropriate to collect a multiplicity of groups of data simultaneously since the supporting columns of various sizes are manufactured on a glass plate through one mask manufacture procedure, and the manufacturing shall not be restricted by production conditions.

Another embodiment of this application discloses a manufacturing method of a display panel, including the abovementioned manufacturing method of a mask.

The display panel of this application may be a twisted nematic (TN) panel, an in-plane switching (IPS) panel, or a multi-domain vertical alignment (VA) panel, and may certainly be any other suitable type of panel.

The foregoing contents are detailed descriptions of this application in conjunction with specific embodiments, and it should not be considered that the specific implementation of this application is limited to these descriptions. Persons of ordinary skill in the art can further make simple deductions or replacements without departing from the concept of this application, and such deductions or replacements should all be considered as falling within the protection scope of this application.

What is claimed is:

1. A manufacturing method of a mask, the manufacturing method of a mask comprising:
simulating, in an experimental environment, an exposure condition of a component correspondingly produced for a mask;
manufacturing the component in the experimental environment, and recording experimental data;
comparing the experimental data with production data recorded in a production environment to form reference data; and
manufacturing the mask of the component according to the reference data.

2. The manufacturing method of a mask according to claim 1, wherein the component comprises a supporting column;
the exposure condition comprises a baking parameter, an exposure parameter and a developing parameter; the experimental data comprises first line width data of the component; the first line width data corresponds to a first opening width of the mask under the same exposure condition; the production data comprises second line width data of the component and second opening width data of the corresponding mask; and the reference data comprises line width ratios of the component to the corresponding mask thereof under the production environment and the experimental environment.

3. The manufacturing method of a mask according to claim 2, wherein the baking parameter comprises a baking temperature and baking time; the developing parameter comprises developing time; and the exposure parameter comprises an exposure dose and the first opening width of the mask.

4. The manufacturing method of a mask according to claim 3, wherein a value of the exposure dose ranges from 40 to 50 mj/cm², and a value of the first opening width ranges between 200 and 300 um.

5. The manufacturing method of a mask according to claim 2, wherein a multiplicity of groups of exposure conditions is provided, and the baking parameter and the developing parameter of each group are the same.

6. The manufacturing method of a mask according to claim 2, wherein the step of simulating the exposure condition of the supporting column in the experimental environment comprises: filtering out a first wavelength, which is different from that in an exposure machine in the production environment, in an exposure machine in the experimental environment.

7. The manufacturing method of a mask according to claim 6, wherein the first wavelength ranges between 300 nm and 350 nm.

8. The manufacturing method of a mask according to claim 1, wherein the supporting column comprises a main supporting column and a sub supporting column; and the exposure condition of manufacturing the main supporting column is the same as that of manufacturing the sub supporting column.

9. A manufacturing method of a mask, the manufacturing method of a mask comprising:
simulating an exposure condition of a supporting column in an experimental environment;
manufacturing the supporting column in the experimental environment, and recording experimental data;
comparing the experimental data with production data recorded in a production environment to form reference data; and
manufacturing the mask of the supporting column according to the reference data, wherein
the exposure condition comprises a baking parameter, an exposure parameter and a developing parameter; the experimental data comprises first line width data of the supporting column; the first line width data corresponds to a first opening width of the mask under the same exposure condition; the production data comprises second line width data of the supporting column and second opening width data of the corresponding mask; the reference data comprises line width ratios of the supporting column to the corresponding mask thereof under the production environment and the experimental environment; a multiplicity of groups of exposure conditions is provided; the baking parameter and the developing parameter of each group are the same;
the baking parameter comprises a baking temperature and baking time; the developing parameter comprises developing time; the exposure parameter comprises an exposure dose and the first opening width of the mask;
a value of the exposure dose ranges from 40 to 50 mj/cm², and a value of the first opening width ranges between 200 and 300 um;
the step of simulating the exposure condition of the supporting column in the experimental environment comprises: filtering out a first wavelength, which is 333 nm, in an exposure machine in the experimental environment;
the supporting column comprises a main supporting column and a sub supporting column; and the exposure condition of manufacturing the main supporting column is the same as that of manufacturing the sub supporting column.

10. A manufacturing method of a display panel, the display panel comprising a mask, and the manufacturing method of a display panel comprising:
simulating, in an experimental environment, an exposure condition of a component correspondingly produced for the mask;
manufacturing the component in the experimental environment, and recording experimental data;
comparing the experimental data with production data recorded in a production environment to form reference data; and
manufacturing the mask of the component according to the reference data.

11. The manufacturing method of a display panel according to claim 10, wherein the component comprises a supporting column;
the exposure condition comprises a baking parameter, an exposure parameter and a developing parameter; the experimental data comprises first line width data of the component; the first line width data corresponds to a first opening width of the mask under the same exposure condition; the production data comprises second line width data of the component and second opening width data of the corresponding mask; and the reference data comprises line width ratios of the supporting column to the corresponding mask thereof under the production environment and the experimental environment.

12. The manufacturing method of a display panel according to claim 11, wherein the baking parameter comprises a baking temperature and baking time; the developing parameter comprises developing time; and the exposure parameter comprises an exposure dose and the first opening width of the mask.

13. The manufacturing method of a display panel according to claim 12, wherein a value of the exposure dose ranges from 40 to 50 mj/cm², and a value of the first opening width ranges between 200 and 300 um.

14. The manufacturing method of a display panel according to claim 11, wherein a multiplicity of groups of exposure conditions is provided, and the baking parameter and the developing parameter of each group are the same.

15. The manufacturing method of a display panel according to claim 11, wherein the step of simulating the exposure condition of the supporting column in the experimental environment comprises: filtering out a first wavelength, which is different from that in an exposure machine in the production environment, in an exposure machine in the experimental environment.

16. The manufacturing method of a display panel according to claim 15, wherein the first wavelength ranges between 300 nm and 350 nm.

17. The manufacturing method of a display panel according to claim 10, wherein the supporting column comprises a main supporting column and a sub supporting column; and the exposure condition of manufacturing the main supporting column is the same as that of manufacturing the sub supporting column.
